(19) United States
(12) Patent Application Publication
(10) Pub. No.: US 2026/0304674 A1
(43) Pub. Date: Oct. 1, 2026

(54) TOOL-FREE SLIDE RAIL AND CHASSIS LOCKING DEVICE

(71) Applicant: MARTAS PRECISION SLIDE CO., LTD., NEW TAIPEI CITY (TW)

(72) Inventor: WAN-LAI CHEN, NEW TAIPEI CITY (TW)

(21) Appl. No.: 19/096,745

(22) Filed: Apr. 1, 2025

(51) Int. Cl. H05K 7/14

(52) U.S. Cl. CPC H05K 7/1489

(57) ABSTRACT

A tool-free slide rail and chassis locking device is installed to an end of an inner rail of a slide rail. the locking device includes a locking body with a fixed base and a locking means and a fixing plate with a first fixing part and a second fixing part perpendicular to each other and fixed onto the locking body and the inner rail respectively. The locking means locks the slide rail and the chassis to an industrial cabinet, the second fixing part extends to form a locking bracket, a locking hole is provided near the upper edge of the inner rail and covered by the locking bracket, and at least one chassis rivet is arranged on an outer side of the chassis for combining and locking the chassis to the inner rail, thus greatly improving the convenience of assembly and operation.

### BACKGROUND OF THE DISCLOSURE

### TECHNICAL FIELD

The present disclosure relates to the technical field of slide rail accessories, and particularly relates to a tool-free slide rail and chassis locking device capable of locking a slide rail and a chassis to an industrial cabinet and connecting and securing the chassis, which greatly improves the convenience of assembly and operation.

### DESCRIPTION OF THE RELATED ART

In a common industrial computer cabinet, multiple servers are installed inside the computer cabinet and mounted onto both sides of the computer cabinet by using a slide rail. The slide rail is usually installed on the pillars of the computer cabinet, so that the servers can be directly pulled out from the computer cabinet for inspection and maintenance. In general, an outer rail is fixed on a support frame, an inner rail is fixed on the side of the servers, and a middle rail is connected between the inner rail and the outer rail to serve as a load-carrying rail in order to extend the range of motion of the servers, so that the inner rail and the middle rail can slide back and forth along the axis of the outer rail relative to the outer rail, and the server can be pulled out from or pushed back into the cabinet freely through the slide rail.

The inner rail and the server are usually fastened together using multiple screws and tools such as screwdrivers, making the installation and removal operations complicated. Therefore, the U.S. Patent U.S. 6,209,979 entitled “Telescoping slide with quick-mount system” was disclosed, which utilizes the top of the slide rail to directly dissect a plurality of L-shaped slots with a plurality of mounting posts on both sides of the chassis, to embed the mounting posts into a plurality of mounting holes in the slide rail to locate the chassis, and to assist a stopper to block one of the mounting holes in the chassis, so as to quickly mount the chassis on the slide rail. However, such operation is carried out by means of a retaining member which serves as a means of engaging the chassis, and in actual use, due to the thickness of the retaining member and the fact that the retaining member is prone to deformation or breakage when it is removed after fixing, the locking effect of the retaining member is not good or even ineffective. Obviously, the related art demands immediate attentions and feasible solutions.

In view of the aforementioned drawbacks of the related art, the discloser of the present disclosure based on years of experience to conduct extensive research and experiment and finally designed and developed a tool-free slide rail and chassis locking device, which includes a locking body, a fixing plate, an inner rail and at least one chassis rivet, and the tool-free slide rail and chassis locking device is installed to an end of an inner rail of the slide rail; the locking body includes a fixed base and a locking means, the locking means is provided for the purpose of locking the slide rail and the chassis to an industrial cabinet, the fixing plate has a first fixing part and a second fixing part perpendicular to each other which are fixed onto the locking body and the inner rail respectively, the second fixing part is extended and formed with a locking bracket, and an upper edge near the inner rail is provided with a locking hole, so that the locking bracket can extend to cover the locking holes, the chassis rivet is installed on the outer side of the chassis and provided for the purpose of combining and locking the chassis to the inner rail. This disclosure not only greatly improves the convenience of assembly and operation, but also reduces the number of parts and provides extra locking functions without the need for additional structures.

### SUMMARY OF THE DISCLOSURE

The primary objective of the present disclosure is to provide a tool-free slide rail and chassis locking device, which is consisted of a locking body, a fixing plate, an inner rail and at least one chassis rivet, and this device has the functions of locking a slide rail and a chassis to an industrial cabinet, and locking the chassis to the inner rail. This disclosure improves the convenience of assembly and operation, and reduces the number of parts as well as the manufacturing and assembly costs without the need for additional structures.

To achieve the aforementioned objective, the tool-free slide rail and chassis locking device of the present disclosure is provided and installed to an end of an inner rail of the slide rail and used for combining and locking the chassis to the inner rail, as well as locking the slide rail and the chassis to an industrial cabinet to prevent them from falling out. The tool-free slide rail and chassis locking device includes: a locking body, further including a fixed base and a locking means, the locking means being installed in an accommodation space formed on the front side of the fixed base, the locking means having a first operating part and a locking part, the locking part extending out of the back of the fixed base, the first operating part linking the locking part and engaging with the industrial cabinet to define a locking, and the back of the locking part being provided with a plurality of first fixing holes; a fixing plate including a first fixing part and a second fixing part perpendicular to each other to form an L-shaped sheet structure, the first fixing part corresponding to the first fixing holes and having a plurality of second fixing holes, and the second fixing part corresponding to the inner rail and having a plurality of third fixing holes, and the second fixing part being extended and provided with a locking bracket; an end of the inner rail corresponding to the third fixing holes and having a plurality of fourth fixing holes, a side of the fourth fixing holes near the upper edge of the inner rail being provided with a locking hole, and a part of the locking bracket extending to cover the locking hole; at least one chassis rivet, installed on an outer side of the chassis. In this way, when the chassis is mounted on the slide rail and the chassis rivet is placed into the locking hole from the top to the bottom, the locking bracket is propped open, and then, after the chassis rivet is completely placed into the locking hole, the locking bracket returns and covers the locking holes again, by a restoring elastic force of the locking bracket, to close the chassis rivet to form a locking, and the chassis rivets can be removed from the locking holes by pulling the locking bracket in order to separate the chassis from the slide rail.

In an embodiment of the present disclosure, an end of the fixing plate is fixed onto a surface of the inner rain through the third fixing holes, so that the locking bracket is defined as being swingable relative to the inner rail, and the locking bracket is normally kept in close contact with the surface of the inner rail, so as to prevent any hindrance during operation.

In another embodiment of the present disclosure, the locking bracket is E-shaped and has a pair of connecting parts to connect an edge of the fixing plate, and the locking bracket is provided with an engaging part corresponding to the locking hole. In addition, the top edge of the engaging part is provided with an inclined guiding part corresponding to the chassis rivet, and the locking bracket is provided with a second operating part corresponding to the middle of the pair of connecting parts, the second operating part links the engaging part to swing in a direction opposite to the surface of the inner rail; and the second operating part is bent to protrude from the surface of the inner rail, so that the second operating part can link the engaging part to swing in a direction opposite to the surface of the inner rail, which is similar to a seesaw structure, and during operation, the bending point of the pair of connecting parts is used as a fulcrum for swinging. In addition, the fixing plate further includes an auxiliary fixing plate extending to an edge of the fixing plate and located on a side of the locking bracket, and the auxiliary fixing plate is provided with a fifth fixing hole, and the inner rail corresponding to the fifth fixing hole is provided with a sixth fixing hole, so as to provide a more stable and secured installation.

In another embodiment of the present disclosure, an end of the locking part is provided with a curved hook, and the second fixing part is provided with a through hole corresponding to the curved hook, and the through hole is located at the center of the distribution positions of the third fixing holes.

### BRIEF DESCRIPTION OF THE DRAWINGS

FIG. 1 is an exploded view of a preferred embodiment of the present disclosure;

FIG. 2 is a perspective view of an assembly of a preferred embodiment of the present disclosure;

FIG. 3 is a first schematic view showing an operation status of a preferred embodiment of the present disclosure;

FIG. 4 is a second schematic view showing an operation status of a preferred embodiment of the present disclosure; and

FIG. 5 is a third schematic view showing an operation status of a preferred embodiment of the present disclosure.

### DESCRIPTION OF THE PREFERRED EMBODIMENTS

The following description together with the attached drawings are provided to enable our examiner to clearly understand the technical contents of the present disclosure.

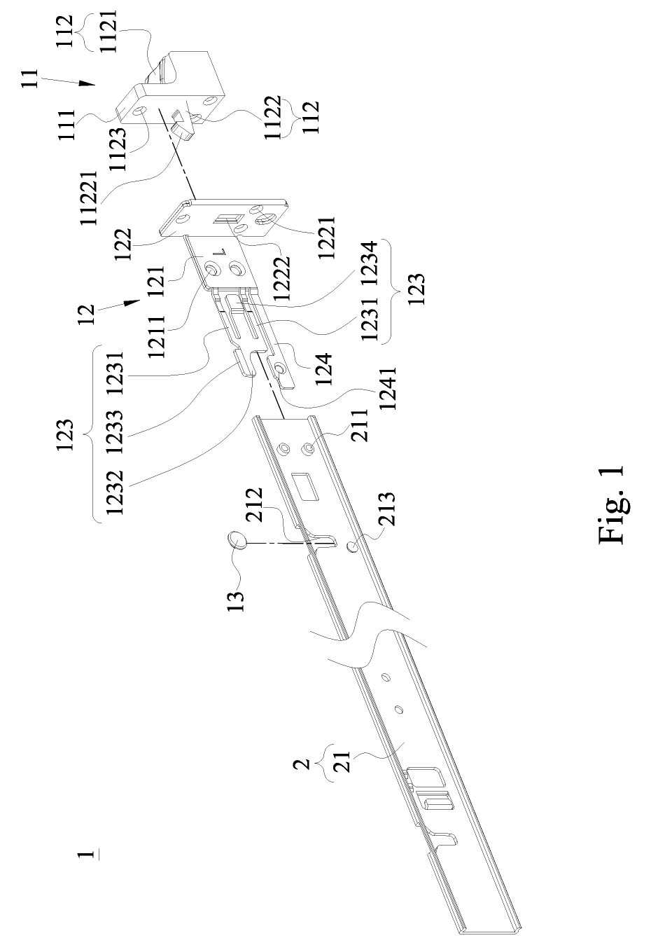

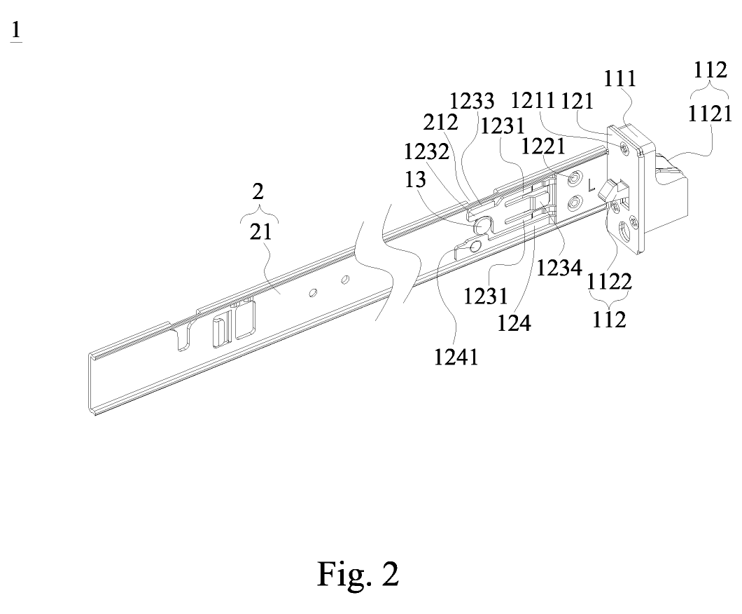

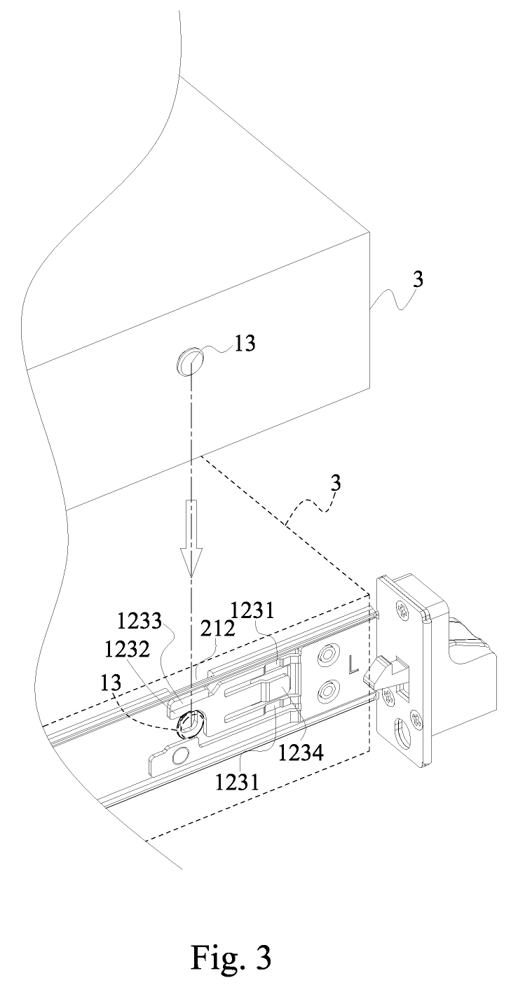

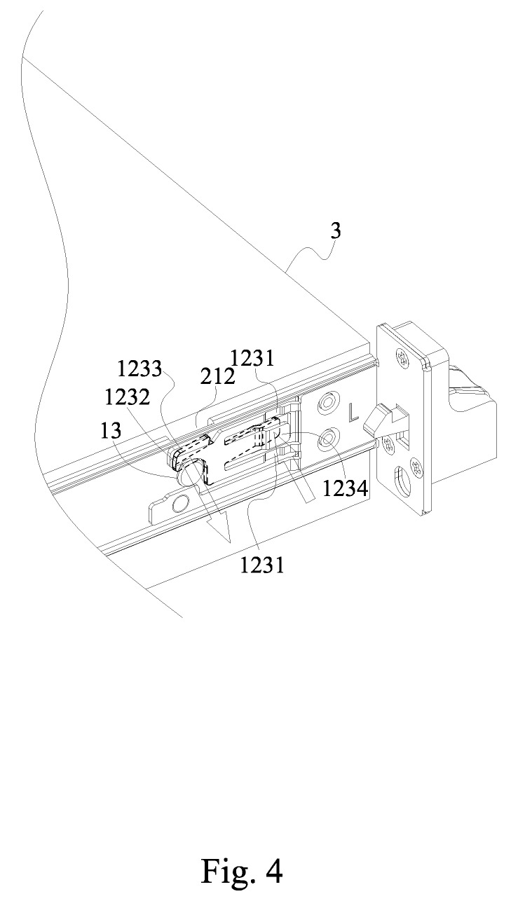

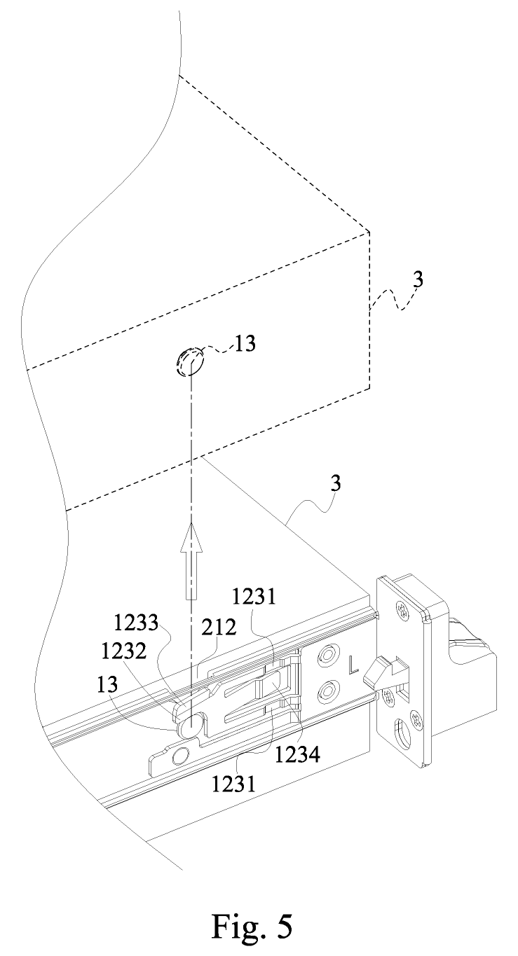

With reference to FIGS. 1, 2 and 3-5 for the exploded view, the perspective view and the schematic views showing different operation statuses of a preferred embodiment of the present disclosure respectively, the tool-free slide rail and chassis locking device 1 of the present disclosure includes a locking body 11, a fixing plate 12, an inner rail 21 and at least one chassis rivet 13. The tool-free slide rail and chassis locking device 1 is installed to an end of the inner rail 21 of the slide rail 2 and provided for the purposes of combining and locking the chassis 3 to the inner rail 21, and locking the slide rail 2 and the chassis 3 to an industrial cabinet and preventing them from falling out.

The locking body 11 includes a fixed base 111 and a locking means 112, the locking means 112 is arranged in an accommodation space 1111 formed on the front of the fixed base 111, and the locking means 112 has a first operating part 1121 and a locking part 1122, and the locking part 1122 extends out of the back of the fixed base 111, and the first operating part 1121 is used to link with the locking part 1122 and engage with the industrial cabinet 4 to define a locking. In addition, the back of the locking part 1122 is provided with a plurality of first fixing holes 1123.

The fixing plate 12 has a first fixing part 121 and a second fixing part 122 perpendicular to each other to form an L-shaped sheet structure, the first fixing part 121 has a plurality of second fixing holes 1211 corresponding to the first fixing holes 1123 respectively, and the second fixing part 122 has a plurality of third fixing holes 1221 corresponding to the inner rail 21, and the second fixing part 1221 extends and has a locking bracket 123. In addition, an end of the fixing plate 12 is fixed onto a surface of the inner rail 21 through the third fixing holes 1221, so that the locking bracket 123 is defined as being swingable relative to the inner rail 21, and the locking bracket 123 is usually kept in close contact with the surface of the inner rail 21. Wherein, an end of the locking part 1122 is provided with a curved hook 11221, and the second fixing part 122 is provided with a through hole 1222 for the curved hook 11221 to pass through, and the through hole 1222 is located at the center of the distribution positions of the third fixing holes 1221.

An end of the inner rail 21 is provided with a plurality of fourth fixing holes 211 corresponding to the third fixing holes 1221 respectively, and a side of the fourth fixing holes 211 near the upper edge of the inner rail 21 is provided with a locking hole 212, and a part of the locking bracket 123 extends to cover the locking hole 212. It is noteworthy that in this embodiment, the locking bracket 123 is E-shaped and has a pair of connecting parts 1231 for connecting to an edge of the fixing plate 12, the locking bracket 123 is provided with an engaging part 1232 corresponding to the locking hole 212, the top edge of the engaging part 1232 is provided with an inclined guiding part 1233 corresponding to the chassis rivet 13, the locking bracket 123 is provided with a second operating part 1234 corresponding to the middle of the pair of connecting parts 1231, and the second operating part 1234 can link with the engaging part 1232 to swing in a direction opposite to a surface of the inner rail 21. In addition, the second operating part 1234 is bent to protrude from the surface of the inner rail 21, such that the second operating part 1234 can link with the engaging part 1232 to swing in a direction opposite to the surface of the inner rail 21. The fixing plate 12 further includes an auxiliary fixing plate 124, extending to an edge of the fixing plate 124 and located on a side of the locking bracket 123, and the auxiliary fixing plate 124 has a fifth fixing hole 1241, and the inner rail 21 has a sixth fixing hole 213 corresponding to the fifth fixing hole 1241.

The chassis rivet 13 is disposed on an outer side of the chassis 3 to define a protruding state.

Accordingly, the actual state of using the tool-free slide rail and chassis locking device 1 of the present disclosure is divided into two parts: First, when the chassis 3 is mounted on the slide rail 2 and the chassis rivet 13 is placed, from top to bottom, into the locking hole 212, the locking bracket 123 is propped open, and then, after the chassis rivet 13 is completely placed into the locking hole 212, the locking bracket 123 returns and covers the locking holes 212 again, by a restoring elastic force of the locking bracket, to close the chassis rivet 13 to define a locking. The chassis rivets 13 can be removed from the locking holes 212 by pulling the locking bracket 123 in the reverse direction in order to separate the chassis 3 from the slide rail 2. Second, the locking means 112 of the present disclosure has a first operating part 1121 and a locking part 1122, and the locking part 1122 extends out of the back of the fixed base 111, and the first operating part 1121 is used for linking the locking part 1122 to engage with the industrial cabinet to define a locking, so as to achieve the purposes of enhancing the convenience of the assembly and operation as well as reducing the number of parts and the manufacturing and assembly costs.

What is claimed is:

1. A tool-free slide rail and chassis locking device, installed to an end of an inner rail of a slide rail, for connecting and locking a chassis to the inner rail, and locking the slide rail and the chassis to an industrial cabinet to prevent from falling out, the tool-free slide rail and chassis locking device comprising:
a locking body comprising a fixed base and a locking means, the locking means being installed in an accommodation space formed on a front of the fixed base, and the locking means comprising a first operating part and a locking part, and the locking part extending out of the fixed base, the first operating part linking the locking part to engage with the industrial cabinet to define a locking, and a back of the locking part being provided with a plurality of first fixing holes; and
a fixing plate comprising a first fixing part and a second fixing part perpendicular to each other to form an L-shaped sheet structure, the first fixing part being provided with a plurality of second fixing holes corresponding to the plurality of first fixing holes, respectively, and the second fixing part being provided with a plurality of third fixing holes corresponding to the inner rail, and the second fixing part extending to have a locking bracket, wherein
the inner rail comprises a plurality of fourth fixing holes formed at the end thereof and corresponding to the plurality of third fixing holes, respectively, and a side of the plurality of fourth fixing holes near an upper edge of the inner rail is provided with a locking hole, and a part of the locking bracket extends to cover the locking hole,
at least one chassis rivet is arranged on an outer side of the chassis, and
when the chassis is mounted on the slide rail and the at least one chassis rivet is inserted into the locking hole from top to bottom, the locking bracket is propped open, and then, after the at least one chassis rivet is completely inserted into the locking hole, the locking bracket returns and covers the locking hole again, by a restoring elastic force of the locking bracket, to close the at least one chassis rivet to define a locking, and the at least one chassis rivet is removable from the locking hole by pulling the locking bracket in a reverse direction in order to separate the chassis from the slide rail.

2. The tool-free slide rail and chassis locking device according to claim 1, wherein an end of the fixing plate is fixed onto a surface of the inner rail through the plurality of third fixing holes, such that the locking bracket is defined as being swingable relative to the inner rail, and the locking bracket is kept in close contact with the surface of the inner rail.

3. The tool-free slide rail and chassis locking device according to claim 1, wherein the locking bracket is substantially E-shaped and comprises a pair of connecting parts for connecting to an edge of the fixing plate, and the locking bracket comprises an engaging part corresponding to the locking hole.

4. The tool-free slide rail and chassis locking device according to claim 3, wherein the engaging part comprises an inclined guiding part disposed at a top edge thereof and corresponding to the at least one chassis rivet, the locking bracket further comprises a second operating part corresponding to a middle of the pair of connecting parts, and the second operating part is capable of linking with the engaging part to swing in a direction opposite the surface of the inner rail.

5. The tool-free slide rail and chassis locking device according to claim 4, wherein the second operating part is bent to protrude from the surface of the inner rail.

6. The tool-free slide rail and chassis locking device according to claim 5, further comprising an auxiliary fixing plate extending to another edge of the fixing plate and located on a side of the locking bracket, wherein
the auxiliary fixing plate comprises a fifth fixing hole, and the inner rail further comprises a sixth fixing hole corresponding to the fifth fixing hole.

7. The tool-free slide rail and chassis locking device according to claim 1, wherein the locking part comprises a curved hook disposed at an end thereof, and the second fixing part comprises a through hole corresponding to the curved hook to allow the curved hook passing through, and the through hole is located at a center of distribution positions of the plurality of third fixing holes.
